(19) United States
(12) Patent Application Publication
(10) Pub. No.: US 2006/0289911 A1
(43) Pub. Date: Dec. 28, 2006

(54) CMOS image sensor

(75) Inventors: Sang-Jun Lee, Daejeon (KR); Yang-Kyu Choi, Daejeon (KR); Dong-Yoon Jang, Daejeon (KR)

Correspondence Address: FOLEY AND LARDNER LLP;SUITE 500, 3000 K STREET NW, WASHINGTON, DC, 20007, US

(73) Assignee: Korea Advanced Institute of Science and Technology

(21) Appl. No.: 11/472,389

(22) Filed: Jun. 22, 2006

(30) Foreign Application Priority Data
Jun. 24, 2005 (KR) 10-2005-0055015

(51) Int. Cl. H01L 31/113

(52) U.S. Cl. 257/292

(57) ABSTRACT

Disclosed is a CMOS image sensor, comprising a photodiode formed in a substrate, a floating diffusion region formed in the substrate in a manner such that it is distanced from the photodiode surrounds the photodiode and a transfer gate formed in a manner such that it is distanced from the photodiode and the floating diffusion region and formed in a boundary area between the photodiode and the floating diffusion region, thereby overlapping the photodiode and the floating diffusion region.

The present invention claims the benefit of Korean Patent Application No. 10-2005-0055015 filed in Korea on Jun. 24, 2005, which is hereby incorporated by reference.

### FIELD OF THE INVENTION

The present invention relates to a complementary metal oxide semiconductor (CMOS) image sensor, and more particularly to a CMOS image sensor having a structure capable of effectively reducing a dark current.

### BACKGROUND OF THE RELATED ART

Generally, CMOS image sensors are manufactured using a field effect transistor (FET) manufacturing process. The CMOS image sensor manufactured through the FET manufacturing process has advantages of consuming lower power, incurring lower cost, achieving higher degree of integration than charge-coupled device (CCD) image sensors. However, the CMOS image sensors also have the disadvantage of having a high dark current.

Problems and disadvantages of the conventional CMOS image sensors will be described with reference to FIG. 1 and FIG. 2.

FIG. 1 is a plan view illustrating a conventional CMOS image sensor, and FIG. 2 is a sectional view taken along a line 2a-2a' in FIG. 1.

Referring to FIG. 1 and FIG. 2, the conventional CMOS image sensor comprises a photodiodes 2 formed on a substrate 1 for generating carriers by receiving light energy, a transfer gate 3 for transferring the carriers generated by the photodiode 2 to a floating diffusion region 4, and a shallow trench isolation oxide 5 for isolating CMOS image sensors from each other.

The conventional CMOS image sensor further comprises a reset FET 7 for outputting a reset signal to be input to the floating diffusion region 4 so that the carriers charged in the floating diffusion region 4 are discharged, a source follower FET 8 serving as a source follower buffer amplifier, and a select transistor 9 for performing switching and addressing.

There are two types of dark currents in the conventional CMOS image sensors.

First dark current is generated from the photodiode 2. That is, the first dark current is generated in a depletion region of a p-n junction formed between the surface of the photodiode 2 and a bulk.

Second dark current is generated from an interface between the photodiode 2 and the shallow trench isolation 5. Here, magnitude of the second dark current generated between the photodiode 2 and the shallow trench isolation 5 is larger than that of the first dark current generated from the photodiode 2. Accordingly, the second dark current is considered as a main dark current.

### SUMMARY OF THE INVENTION

Accordingly, an object of the present invention is to solve at least the problems and disadvantages of the background art.

An aspect of the present invention is to provide a CMOS image sensor capable of effectively reducing dark current and enhancing the transfer characteristic of carriers from a photodiode to a floating diffusion region.

In order to achieve the above-described and other aspects of the present invention, according to one aspect of the present invention, there is provided a CMOS image sensor comprising a photodiode formed on a substrate, a floating diffusion region formed on the substrate in a manner such that it is distanced from the photodiode in a horizontal direction by a predetermined distance and it surrounds the photodiode, a transfer gate formed in a boundary area of the photodiode and the floating diffusion region so as to overlap the photodiode and the floating diffusion region, and an shallow trench isolation formed in the substrate so as to be distanced from the floating diffusion region in a horizontal direction.

The photodiode may have a circular plane shape or an oval plane shape, and the transfer gate may have a circular hall in a center portion thereof and may have a plane of a ring shape.

The photodiode, the transfer gate, the floating diffusion region and the shallow trench isolation are formed to be symmetric to each other.

The floating diffusion region has a rectangular plane shape and has a circular hall in a center portion of the rectangular plane.

Thanks to the above-described structure, the CMOS image sensor can effectively reduce a dark current between the photodiode and the shallow trench isolation because carriers generated by light energy incident onto the photodiode can be transferred to the floating diffusion region in all directions via the transfer gate.

### BRIEF DESCRIPTION OF THE DRAWINGS

The invention will be described in detail with reference to the following drawings in which like numerals refer to like elements.

FIG. 1 is a plan view illustrating a CMOS image sensor according to the conventional art;

FIG. 2 is a sectional view illustrating the conventional CMOS image sensor taken along the line 2a-2a';

FIG. 3 is a plan view illustrating a CMOS image sensor according to one embodiment of the present invention; and

FIG. 4 is a sectional view taken along the line 4a-4a', illustrating the CMOS image sensor according to the embodiment of the present invention.

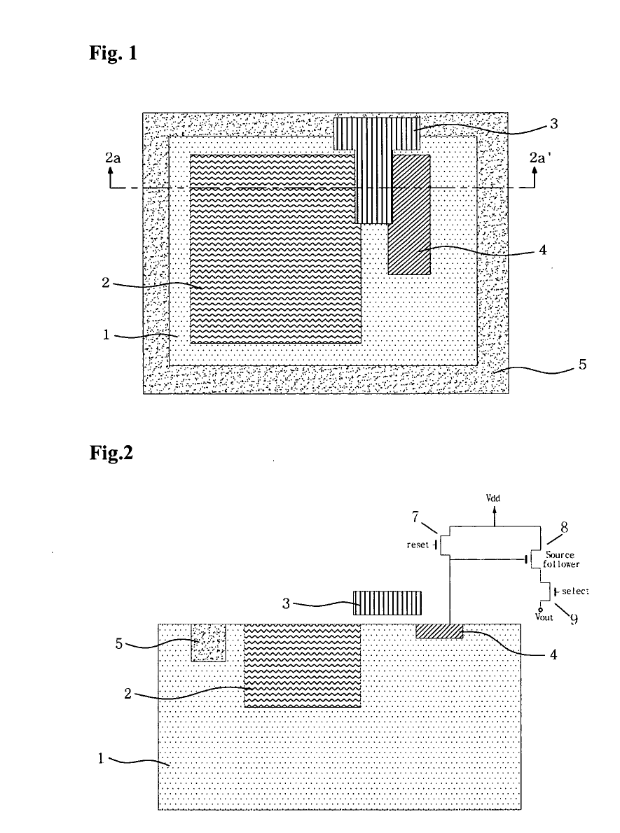

### DETAILED DESCRIPTION OF PREFERRED EMBODIMENTS

Advantages and features of the present invention and methods of accomplishing the same may be understood more readily by reference to the following detailed description of preferred embodiments and the accompanying drawings.

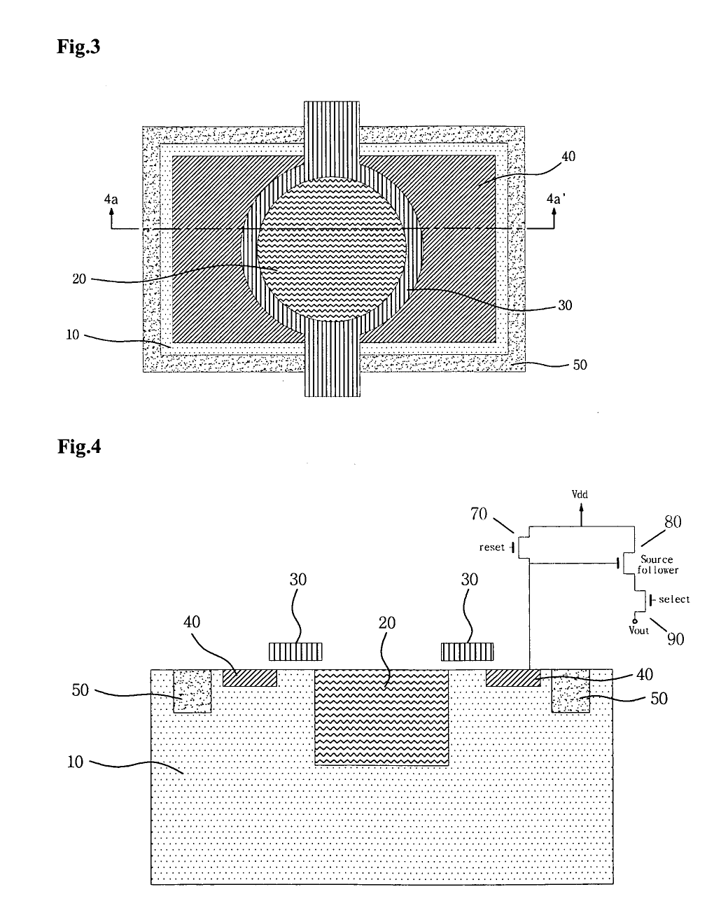

Hereinafter, a CMOS image sensor according to one embodiment of the present invention will be described with reference to FIG. 3 and FIG. 4.

FIG. 3 is a plan view illustrating a CMOS image sensor according to one embodiment of the present invention and FIG. 4 is a sectional view taken along the line 4a-4a', illustrating the CMOS image sensor according to the embodiment of the present invention.

Referring to FIG. 3 and FIG. 4, the CMOS image sensor according to one embodiment of the present invention comprises a photodiode 20 formed on a substrate for generating carriers by receiving light energy, a floating diffusion region 40 disposed in a manner such that it is distanced from the photodiode 20 and it surrounds the photodiode 20, a transfer gate 30 formed in a boundary area between the photodiode 20 and the floating diffusion region 40 to overlap the photodiode 20 and the floating diffusion region 40, and an shallow trench isolation 50 for preventing interference between adjacent image sensors.

Referring to FIG. 4, in the CMOS image sensor according to the present invention, the transfer gate 30, the floating diffusion region 40 and the shallow trench isolation 50 are symmetrically arranged with respect to the photodiode 20.

If the photodiode 20 has a circular plane shape, the floating diffusion region 40 is formed to surround the photodiode 20 and to be distanced from the photodiode 20 in a horizontal direction. The floating diffusion region 40 has a circular plane shape or a rectangular plane shape, having a circular hall in a center portion thereof, so that the photodiode 20 is disposed in the circular hall. The transfer gate 30 is formed to be distanced from the photodiode 20 and the floating diffusion region 40 in a vertical direction. The transfer gate 30 is formed in a boundary between the photodiode 20 and the floating diffusion region 40 so that an area of the transfer gate 30 overlap an area of the photodiode 20 and an area of the floating diffusion region 40. The transfer gate 30 has a plane having a ring shape, having a circular hall in a center portion thereof, so that the photodiode 20 is disposed in the center hollow.

The shallow trench isolation 50 is formed in the substrate 10 to surround the floating diffusion region 40 in order to inhibit interference between adjacent CMOS image sensors.

Hereinafter, the operation of the CMOS image sensor according to the one embodiment of the present invention will be described below.

When light is incident onto the photodiode 20 on the substrate 10, the photodiode 20 generates carriers. The carriers generated from the photodiode 20 are transferred to the floating diffusion region 40 via the transfer gate 30 disposed around the photodiode 20.

If the photodiode 20 has a circular plane shape or an oval plane shape, the transfer gate 30 is formed to surround the photodiode 20, thereby forming a ring shape. The carriers generated from the photodiode 20 can be transferred to the floating diffusion region 40 in all directions of the transfer gate 30. Accordingly, carrier transfer efficiency of the transfer gate 30 is enhanced.

The carriers are first transferred to the transfer gate 30, and then transferred to the floating diffusion region 40 disposed around the transfer gate 30. Since the floating diffusion region 40 disposed around the circumferential edge of the transfer gate 30 is formed in a manner of surrounding the photodiode 20, it has a large area. The carriers transferred from the photodiode 20 are transferred to the floating diffusion region 40 having a large area before they are discharged into the shallow trench isolation 50. Accordingly, a dark current between the photodiode 20 and the shallow trench isolation 50 effectively decreases.

Further, it is difficult for the carriers transferred to the floating diffusion region 40 to reach the shallow trench isolation 50, interference between adjacent CMOS image sensors is prevented.

As described above, since the CMOS image sensor according to the present invention is formed in a manner such that the floating diffusion region 40 surrounds the photodiode 20, the floating diffusion region 40 abuts the photodiode 20 in all directions, that is, the floating diffusion region 40 abuts the photodiode 20 along all of the edges of the photodiode 20. Accordingly, the carriers generated from the photodiode 20 can be transferred to the floating diffusion region 40 in all directions, so that carrier transfer efficiency is enhanced. Further, since the carriers reach the floating diffusion region 40 before the carriers reach the shallow trench isolation 50, dark current can be reduced.

Since the CMOS image sensor according to the present invention is structured in a manner that the transfer gate 30 and the floating diffusion region 40 surround the photodiode 20, the distance between respective photodiodes of adjacent CMOS image sensors is larger than that in the conventional CMOS image sensors. Accordingly, interference between adjacent CMOS image sensors isolated by the shallow trench isolation 50 is effectively reduced.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation, and the present invention will only be defined by the appended claims. Further, all variations and modifications induced from meanings, scopes and equivalents of the appended claims are construed to be includes in the scope of the present invention.

The CMOS image sensor according to the present invention has the following advantages.

First, the CMOS image sensor has high performance since carriers generated by the photodiode when light is incident onto the photodiode are effectively transferred to the floating diffusion region.

Second, the CMOS image sensor has a relatively small dark current between the photodiode and the shallow trench isolation in comparison with conventional CMOS image sensors.

Third, since the transfer gate is formed to overlap the photodiode and to surround the photodiode in all directions, that is, the transfer gate abuts the floating diffusion region in all directions, efficiency of carrier transfer from the photodiode to the floating diffusion region is enhanced.

What is claimed is:

1. A CMOS image sensor, comprising:
a photodiode formed in a substrate;
a floating diffusion region formed in the substrate in a manner such that it is distanced from the photodiode surrounds the photodiode;
a transfer gate formed in a manner such that it is distanced from the photodiode and the floating diffusion region and formed in a boundary area between the photodiode and the floating diffusion region, thereby overlapping the photodiode and the floating diffusion region; and
a shallow trench isolation distanced from the floating diffusion region.

2. The CMOS image sensor according to claim 1, wherein the photodiode has a circular plane shape or an oval plane shape.

3. The CMOS image sensor according to claim 1, wherein a plane of the transfer gate has a circular hall at a center portion thereof.

4. The CMOS image sensor according to claim 1, wherein the plane of the transfer gate is a ring shape.

5. The CMOS image sensor according to claim 3, wherein a section of the transfer gate, a section of the floating diffusion region, and a section of the shallow trench isolation are symmetric.

6. The CMOS image sensor according to claim 1, wherein the floating diffusion region has a rectangular plane shape.

7. The CMOS image sensor according to claim 6, wherein the plane of the floating diffusion region has a circular hall in a center portion thereof.
